(19) United States
(12) Patent Application Publication
(10) Pub. No.: US 2023/0162992 A1
(43) Pub. Date: May 25, 2023

(54) METHOD FOR MANUFACTURING SEMICONDUCTOR DEVICE, METHOD FOR MANUFACTURING DEVICE PROVIDED WITH SEMICONDUCTOR DEVICE, SEMICONDUCTOR DEVICE, AND DEVICE PROVIDED WITH SEMICONDUCTOR DEVICE

(71) Applicant: TOHOKU UNIVERSITY, Sendai-shi (JP)

(72) Inventors: Takafumi FUKUSHIMA, Sendai-shi (JP); Tetsu TANAKA, Sendai-shi (JP); Hisashi KINO, Sendai-shi (JP); Yuki SUSUMAGO, Sendai-shi (JP)

(21) Appl. No.: 18/159,173

(22) Filed: Jan. 25, 2023

Related U.S. Application Data
(63) Continuation of application No. PCT/JP2020/029503, filed on Jul. 31, 2020.

(51) Int. Cl. H01L 21/56; H01L 23/00; H01L 21/683; H01L 23/29; H01L 23/31

(52) U.S. Cl. CPC H01L 21/568; H01L 21/561; H01L 24/24; H01L 21/6835; H01L 23/293; H01L 23/3135; H01L 24/19; H01L 24/20; H01L 24/82; H01L 2224/24137; H01L 2224/82005; H01L 2221/68386; H01L 2224/19; H01L 2224/214; H01L 2224/24101; H01L 2224/24195; H01L 2924/12041; H01L 2924/19041; H01L 2924/12043; H01L 2924/1426; H01L 25/167

(57) ABSTRACT

A method for manufacturing a semiconductor device provided with a semiconductor chip includes: disposing the semiconductor chip such that an electrode of the semiconductor chip is abutted against a peeling portion provided on a substrate; forming an anchor portion, which defines a position of the semiconductor chip and has flexibility so as to be freely bendable, such that the anchor portion covers the peeling portion and the semiconductor chip; forming a sealing portion that is abutted against the anchor portion and has flexibility so as to be freely bendable; and separating the peeling portion and the substrate from the semiconductor chip and the anchor portion and exposing the electrode of the semiconductor chip. The anchor portion is formed by at least one of a vapor phase deposition method, a spray coating method, and an inkjet method.

### TECHNICAL FIELD

The invention relates to a method for manufacturing a semiconductor device, a method for manufacturing a device provided with a semiconductor device, a semiconductor device, and a device provided with a semiconductor device.

### BACKGROUND ART

In recent years, in semiconductor packaging, fan out wafer level packaging (FOWLP) is known as a mainstream technique for mobile applications such as portable electronic devices such as smartphones (for example, see PTL 1). In addition, as a technique for use in mobile applications, a technique adopting a flexible display is also known (for example, see PTL 2), which may include a display that is freely bendable.

### CITATION LIST

### Patent Literature

PTL 1: WO2018/081705

PTL 2: JP2019-211778A

### SUMMARY OF INVENTION

### Technical Problem

However, in semiconductor packaging, in a method of filling with a sealing resin, the sealing resin may be cured in a state in which a semiconductor chip is moved by a flow of the sealing resin and is thus deviated from a prescribed position (called a die shift), which may lead to defects such as defective wiring to the semiconductor chip. In addition, in a freely bendable product such as a flexible display, there is a possibility that the deviation further increases from the state of being deviated from the prescribed position due to bending of the display.

### Solution to Problem

A method for manufacturing a semiconductor device according to the invention includes at least the following configuration.

A method for manufacturing a semiconductor device provided with a semiconductor chip includes:

disposing the semiconductor chip such that an electrode of the semiconductor chip is abutted against a peeling portion provided on a substrate;

forming an anchor portion, which defines a position of the semiconductor chip and has flexibility so as to be freely bendable, such that the anchor portion covers the peeling portion and the semiconductor chip;

forming a sealing portion that is abutted against the anchor portion and has flexibility so as to be freely bendable; and

separating the peeling portion and the substrate from the semiconductor chip and the anchor portion and exposing the electrode of the semiconductor chip.

A method for manufacturing a device provided with a semiconductor device according to the invention includes:

manufacturing a device by combining another component with a semiconductor device manufactured by the method for manufacturing a semiconductor device described above.

A semiconductor device according to the invention has at least the following configuration.

A semiconductor device provided with a semiconductor chip includes:

a semiconductor chip whose one surface is formed with an electrode;

an anchor portion that covers the semiconductor chip other than the surface on which the electrode is formed, and has flexibility so as to be freely bendable;

a sealing portion that is abutted against the anchor portion and has flexibility so as to be freely bendable; and

a wiring connected to the electrode of the semiconductor chip.

A device according to the invention includes the semiconductor device described above.

### BRIEF DESCRIPTION OF DRAWINGS

FIG. 1 is a cross-sectional view showing an example of a semiconductor device provided with a semiconductor chip according to an embodiment of the invention.

FIG. 2 is a flowchart showing an example of a method for manufacturing a semiconductor device according to the embodiment of the invention.

FIG. 3 shows an example of the method for manufacturing a semiconductor device. (a) is a schematic cross-sectional view showing an example of a state in which a semiconductor chip is placed such that a surface on which an electrode is formed is abutted against a first peeling portion (Tape A) provided on a wafer (first substrate). (b) is a perspective view of (a). (c) is a schematic cross-sectional view showing an example of a state in which an anchor portion (anchor layer) is formed. (d) is a perspective view of (c).

FIG. 4 shows the example of the method for manufacturing a semiconductor device. (a) shows an example of a state in which PDMS is formed on the anchor portion (anchor layer), and a second peeling portion (Tape B) and a second substrate are provided. (b) is a perspective view of (a). (c) shows an example of a state in which the first peeling portion and the first substrate are separated from the semiconductor chip and the anchor portion (anchor layer), and the electrode of the semiconductor chip is exposed. (d) is a perspective view of (c).

FIG. 5 shows the example of the method for manufacturing a semiconductor device. (a) shows an example of a state in which SBL (buffer layer) is formed. (b) is a perspective view of (a). (c) shows an example of a state in which a rewiring layer is formed. (d) is a perspective view of (c).

FIG. 6 shows the example of the method for manufacturing a semiconductor device. (a) is a schematic cross-sectional view showing an example of a semiconductor device in which the second substrate and the second peeling portion are separated from PDMS. (b) is a perspective view of (a). (c) is a schematic view showing an example of the semiconductor device in a bent state.

FIG. 7 shows photographs showing effects of the method for manufacturing a semiconductor device according to the present embodiment of the invention. (a) is a photograph showing an example of a position of the semiconductor chip in a case where the anchor portion (anchor layer) of the semiconductor device according to the present embodiment of the invention is provided. (b) is a photograph as a comparative example showing an example of a die shift in a case where no anchor portion is used.

FIG. 8 shows an example of a mechanism that prevents positional deviation of the semiconductor chip in a case where the anchor portion is provided. (a) is a schematic cross-sectional view showing a state in which the semiconductor chip is disposed on the first peeling portion, the anchor portion is formed, and PDMS is injected. (b) is a schematic cross-sectional view showing an example of gas removal and curing of PDMS. (c) is a schematic cross-sectional view showing an example of thermal peeling. (d) is a schematic cross-sectional view showing an example of a state in which the first peeling portion and the like is separated from the semiconductor chip and the anchor layer.

FIG. 9 shows, as a comparative example, an example of a mechanism of a die shift in a case where no anchor layer (anchor portion) is used. (a) is a schematic cross-sectional view showing a state in which the semiconductor chip is disposed on the first peeling portion and PDMS is injected. (b) is a schematic cross-sectional view showing an example of gas removal and curing of PDMS. (c) is a schematic cross-sectional view showing an example of thermal peeling. (d) is a schematic cross-sectional view showing an example of a state in which the first peeling portion and the like is separated from the semiconductor chip and PDMS (sealing portion).

FIG. 10 shows an example of a device provided with a semiconductor device.

### DESCRIPTION OF EMBODIMENTS

A method for manufacturing a semiconductor device according to an embodiment of the invention enables manufacture of a highly integrated semiconductor package by forming an anchor portion (an anchor layer or the like) that prevents movement of a semiconductor chip in semiconductor packaging.

Specifically, the method for manufacturing a semiconductor device includes: disposing the semiconductor chip such that an electrode of the semiconductor chip is abutted against a peeling portion provided on a substrate; forming an anchor portion, which defines a position of the semiconductor chip and has flexibility so as to be freely bendable, such that the anchor portion covers the peeling portion and the semiconductor chip; forming a sealing portion that is abutted against the anchor portion and has flexibility so as to be freely bendable; and separating the peeling portion and the substrate from the semiconductor chip and the anchor portion and exposing the electrode of the semiconductor chip.

In addition, a method for manufacturing a device provided with a semiconductor device according to the invention includes: manufacturing a device by combining another component with a semiconductor device manufactured by the method for manufacturing a semiconductor device described above.

In addition, a semiconductor device according to the present embodiment of the invention includes: a semiconductor chip whose one surface is formed with an electrode; an anchor portion that covers the semiconductor chip other than the surface on which the electrode is formed, and has flexibility so as to be freely bendable; a sealing portion that is abutted against the anchor portion and has flexibility so as to be freely bendable; and a wiring connected to the electrode of the semiconductor chip.

In addition, a device according to the present embodiment of the invention includes: a semiconductor device including a semiconductor chip.

Hereinafter, the present embodiment of the invention will be described with reference to the drawings. The present embodiment of the invention includes, but is not limited to, contents shown in the drawings. In the following description of the drawings, the same reference numerals are given to the same portions as those already described, and a repeated description thereof will be partially omitted.

In addition, the drawings are schematic, and a relationship between a thickness and a planar dimension, a proportion of a thickness of each layer, and the like may be different from reality. In addition, the drawings may contain parts that differ from each other in dimensional relationships and proportions.

In addition, the present embodiment described below exemplifies a method and the like for embodying a technical idea of the invention, and the technical idea of the invention does not specify materials, shapes, structures, arrangements, and the like of constituent elements to those described below. Various modifications can be made to the technical idea of the invention within a technical scope described in the claims.

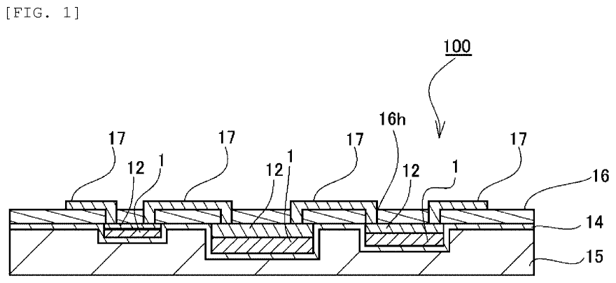

FIG. 1 is a cross-sectional view showing an example of a semiconductor device according to the present embodiment of the invention.

A semiconductor device 100 includes a semiconductor chip 1, an anchor portion 14 (also referred to as an anchor layer), a sealing portion 15, a wiring 17, and the like. In the example shown in FIG. 1, the semiconductor device 100 also includes a buffer layer 16 (also referred to as a buffer portion).

The semiconductor chip 1 is an LED, a micro LED (for example, having a substantially rectangular parallelepiped shape whose one side has a length of about 1 μm to 200 μm), an integrated circuit, a semiconductor sensor, a capacitor, a transistor, a semiconductor sensor, or the like, and is formed in a chip shape.

In the example shown in FIG. 1, the semiconductor chip 1 is formed in a substantially rectangular parallelepiped shape, and an electrode 12 is formed on one surface of the semiconductor chip 1.

The anchor portion 14 is formed so as to cover the semiconductor chip 1 other than the surface on which the electrode 12 is formed.

In the example shown in FIG. 1, the sealing portion 15 is formed so as to be abutted against the anchor portion 14.

In addition, in the example shown in FIG. 1, the buffer layer 16 is formed on an upper portion of the sealing portion 15 or on an upper portion of a part of the semiconductor chip 1.

In addition, in the example shown in FIG. 1, the wiring 17 (rewiring layer) is formed on an upper portion of the buffer layer 16, and the wiring 17 is electrically connected to the electrode 12 of the semiconductor chip 1 via a via hole 16h formed in the buffer layer 16.

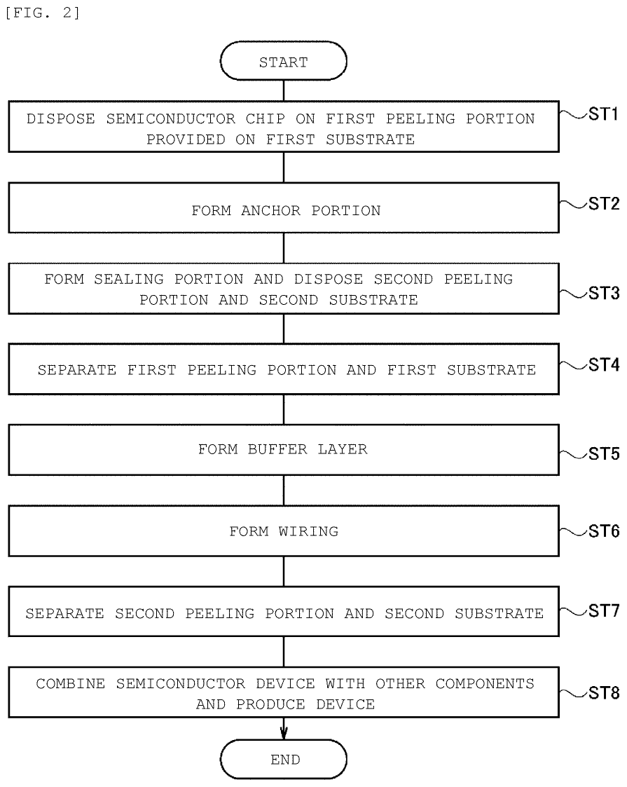

FIG. 2 is a flowchart showing an example of a method for manufacturing the semiconductor device 100 according to the present embodiment of the invention.

The example of the method for manufacturing the semiconductor device 100 will be described with reference to a flowchart shown in FIG. 2 and FIGS. 3 to 6. Hereinafter, a method for manufacturing a semiconductor device adopting die-first/face-down fan out wafer level packaging (FOWLP) as a method for mounting the semiconductor chip 1 will be described. However, the invention is not limited to this embodiment as long as a die shift can be prevented by forming an anchor portion that has flexibility so as to be freely bendable.

The method for manufacturing the semiconductor device 100 includes: disposing a semiconductor chip on a first peeling portion provided on a first substrate (ST1); forming an anchor portion (ST2); forming a sealing portion and disposing a second peeling portion and a second substrate (ST3); separating the first peeling portion and the first substrate (ST4); forming a buffer layer (ST5), forming a wiring (ST6), separating the second peeling portion and the second substrate (ST7), and the like.

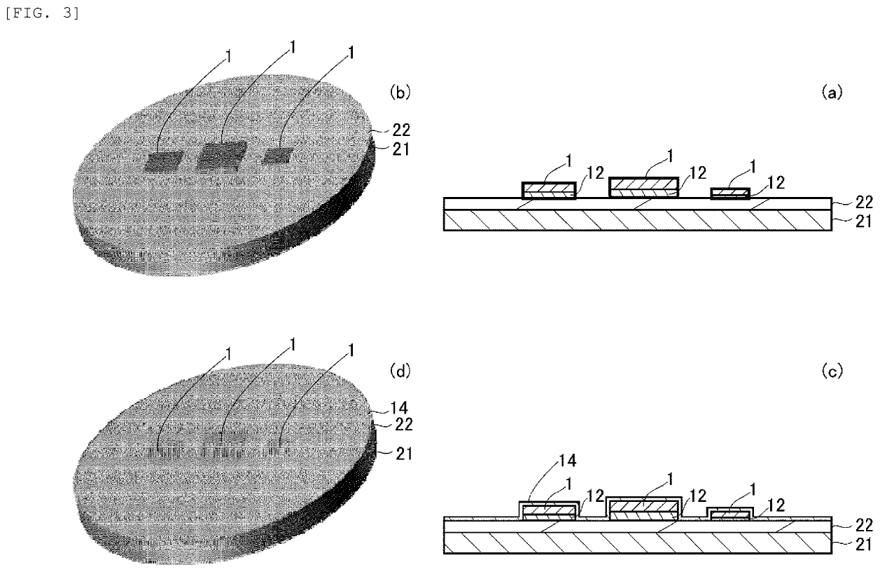

Specifically, in step ST1, as shown in (a) and (b) of FIG. 3, a peeling portion 22 (first peeling portion) is formed on a substrate 21 (also referred to as a first substrate or a first carrier) such as a silicon wafer.

The peeling portion 22 is made of, for example, a functional bonding member. The functional bonding member is formed of a weak adhesive bonding material (such as a bonding tape that can be peeled off at a high temperature). To be weak adhesive means that peel strength decreases at a predetermined or higher temperature (for example, about 130° C. (set temperature)). In the present embodiment, a thermal peeling tape (tape A) is adopted as the peeling portion 22. The substrate 21 on which the peeling portion 22 is provided in advance may be prepared.

Next, the semiconductor chip 1 is disposed at a predetermined position on the peeling portion 22. Specifically, the semiconductor chip 1 is disposed on the peeling portion 22 such that the electrode 12 formed on the one surface of the semiconductor chip 1 is abutted against the peeling portion 22.

Examples of a material for forming the peeling portion 22 include a light peeling material such as a UV peeling tape that can be peeled off by UV light irradiation, a peeling material that can be peeled off by using laser ablation of, for example, an excimer laser of deep or deeper ultraviolet light, and a peeling material that can be peeled off by irradiation with laser light of, for example, ultraviolet light, visible light, and near-infrared light.

The peeling portion 22 may also be, for example, a spin coating type thermal peeling material, instead of a tape type thermal peeling material.

The peeling portion 22 may also be made of a material that can be mechanically peeled off by using a tool such as a wedge.

The peeling portion 22 may also be formed of a material that can be peeled off by a solvent.

That is, the peeling portion 22 is formed of a material that can be peeled by at least one method of thermal peeling, optical peeling (including a laser), mechanical peeling (including a method of peeling with a high-pressure jet or the like), and solvent peeling.

In step ST2, as shown in (c) and (d) of FIG. 3, the anchor portion 14 (anchor portion) is formed so as to cover the peeling portion 22 and upper and side surfaces of the semiconductor chip 1. Specifically, the anchor portion 14 is formed so as to cover a portion of the semiconductor chip 1 other than the surface on which the electrode 12 is formed. The anchor portion 14 defines a position of the semiconductor chip 1 such that the position of the semiconductor chip 1 does not deviate. In the present embodiment, even when a size of the semiconductor chip 1 is less than 1 mm, a die shift can be prevented by providing the anchor portion 14.

The anchor portion 14 may be formed by a vapor phase deposition method, a spray coating method, or the like, and any method may be used as long as the anchor portion 14 can be finished with flexibility.

An example of a material for forming the anchor portion 14 includes a polyurea such as a combination of 4,4′-diaminodiphenylmethane and 4,4′-diphenylmethane diisocyanate, a combination of 1,9-diaminononane and 1,9-diisocyanate nonane, and a combination of 1,5-diaminopentane and 1,5-diisocyanate pentane. In addition, a parylene can also be used. Plasticity of such materials imparts flexibility to the anchor portion so that the anchor portion is freely bendable.

A thickness of the anchor portion 14 may be any thickness as long as the anchor portion 14 can prevent positional deviation of the semiconductor chip 1 at the time of forming the sealing portion in the subsequent steps, and is, for example, 0.1 μm to 100 μm, preferably 0.5 μm to 10 μm, and most preferably 1 μm to 3 μm.

In the present embodiment, a film of an aromatic polyurea of a combination of 4,4′-diaminodiphenylmethane and 4,4′-diphenylmethane diisocyanate is uniformly formed by a vapor deposition polymerization method so as to cover the peeling portion 22 and the upper and side surfaces of the semiconductor chip 1, thereby forming the anchor portion 14 having a thickness of 1 μm. As another embodiment, an aliphatic polyurea such as a combination of 1,9-diaminononane and 1,9-diisocyanate nonane or a combination of 1,5-diaminopentane and 1,5-diisocyanate pentane may also be obtained by a vapor deposition polymerization method. In the case of the aliphatic polyurea, although a residence time of an aliphatic monomer on a substrate is too short for a polymerization reaction to occur when a temperature of the substrate is high, a film can be sufficiently formed if the temperature of the substrate is −20° C. or lower.

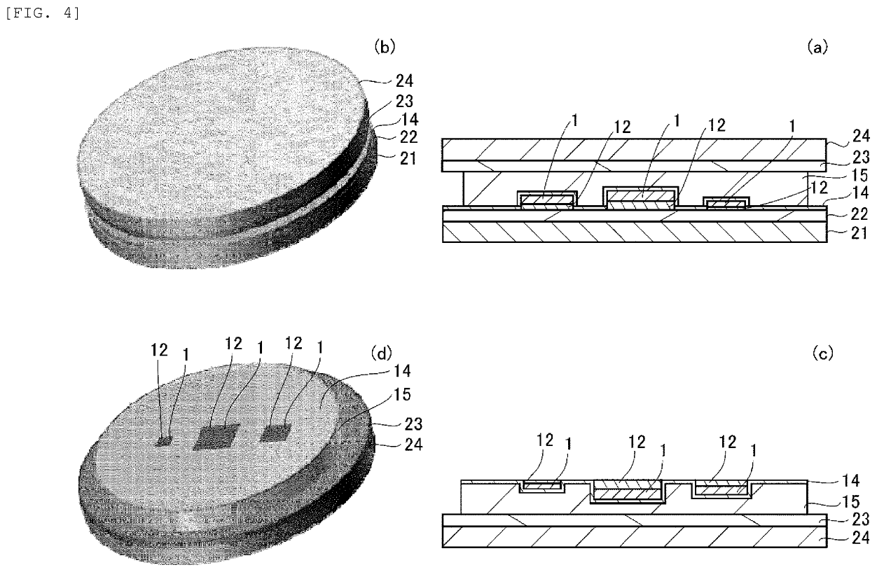

In step ST3, as shown in (a) and (b) of FIG. 4, a step of forming the sealing portion 15 and disposing a peeling portion 23 (second peeling portion) and a substrate 24 (also referred to as a second substrate or a second carrier) is performed.

In the present embodiment, after a liquid or semi-liquid resin (for example, silicone rubber (PDMS: polydimethylsiloxane)) is applied onto the anchor portion 14 as a material for forming the sealing portion 15, the substrate 24 (second substrate) such as a silicon wafer whose lower surface is provided with the peeling portion 23 is disposed on the sealing portion 15.

As the peeling portion 23, for example, a thermal peeling tape (tape B) is adopted. As the thermal peeling tape (tape B), a tape whose peeling strength decreases at a predetermined or higher temperature (for example, about 150° C. (a set temperature higher than that of the peeling portion 22)) is adopted.

Then, in a state in which the material (PDMS or the like) for forming the sealing portion 15 is disposed between the substrate 21 and the substrate 24, defoaming (gas removal) from PDMS is performed for a predetermined time (for example, 30 minutes) at a predetermined degree of vacuum (for example, 10 kPa) by using a vacuum device, and compression molding is performed at a predetermined pressure (for example, 0.7 MPa), thereby forming the sealing portion 15.

Next, in step ST4, the substrate 21 (first substrate) and the peeling portion 22 (first peeling portion) are separated from the semiconductor chip 1 and the anchor portion 14, and the electrode 12 of the semiconductor chip 1 is exposed and up-down inverted as shown in (c) and (d) of FIG. 4.

Specifically, the substrate 21 (first substrate) and the peeling portion 22 (first peeling portion) are heated (for example, for 2 minutes) at a predetermined temperature (about 130° C.) so as to be separated from the semiconductor chip 1 and the anchor portion 14.

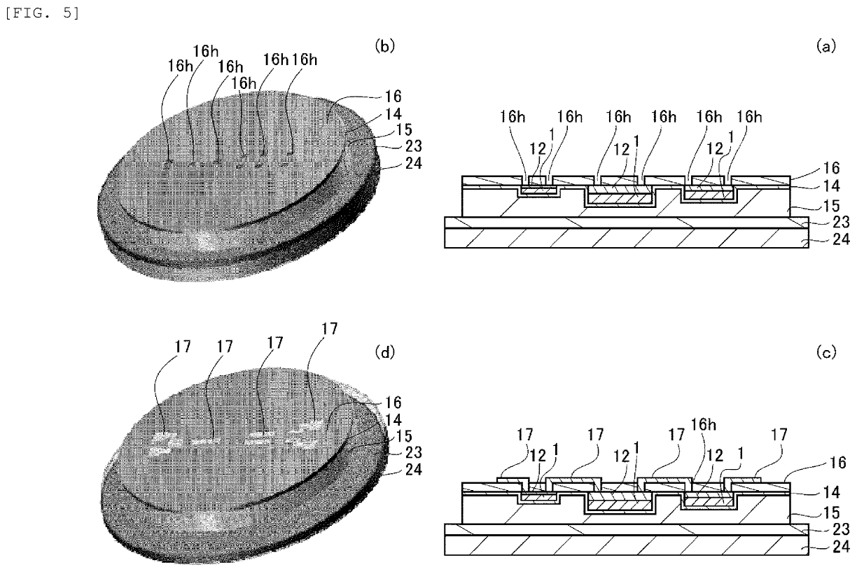

In step ST5, as shown in (a) and (b) of FIG. 5, the thin buffer layer 16 (SBL: stress buffer layer) is formed on the semiconductor chip 1 and the anchor portion 14. The buffer layer 16 may be formed by a vapor phase deposition method, a spin coating method, a spray coating method, or the like. As a material for forming the buffer layer 16, an insulating material such as a parylene may be adopted.

Next, the via hole 16h is formed in the buffer layer 16 by an etching technique, a laser processing technique, or the like. The via hole 16h is formed at a position above the electrode 12 of the semiconductor chip 1.

In step ST6, as shown in (c) and (d) of FIG. 5, the wiring 17 having a predetermined pattern is formed on the buffer layer 16. The wiring 17 is electrically connected to the electrode 12 of the semiconductor chip 1 via the via hole 16h. Specifically, in the present embodiment, the wiring 17 is formed into the predetermined wiring pattern by a metal material such as titanium or gold using a physical vapor deposition technique, a photolithography process, wet etching, or the like.

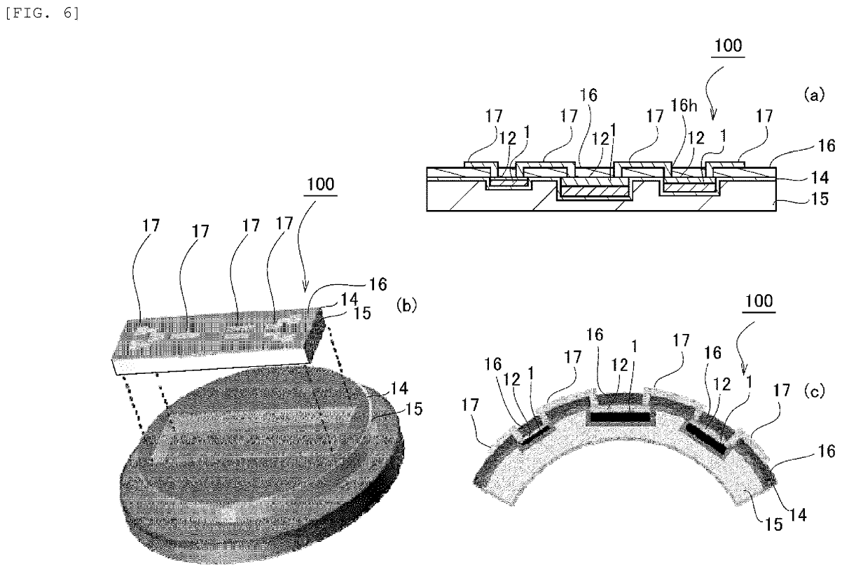

Next, in step ST7, the peeling portion 23 (second peeling portion) and the substrate 24 (second substrate) shown in (c) of FIG. 5 are separated from the sealing portion 15, and thus the semiconductor device 100 is manufactured as shown in (a) and (b) of FIG. 6.

Specifically, the substrate 24 (second substrate) and the peeling portion 23 (second peeling portion) are heated (for example, for 2 minutes) at a predetermined temperature (about 150° C.) so as to be peeled off from the sealing portion 15.

As shown in (a) of FIG. 6, since the sealing portion 15 and the like have flexibility, the semiconductor device 100 is freely bendable.

Next, in step ST8, the semiconductor device 100 described above is combined with other components such as various sensors, a driving unit, and a housing portion so as to produce a device provided with the semiconductor device 100.

The inventors of the present application confirm effects of the method for manufacturing a semiconductor device according to the present embodiment of the invention by actually manufacturing a semiconductor device.

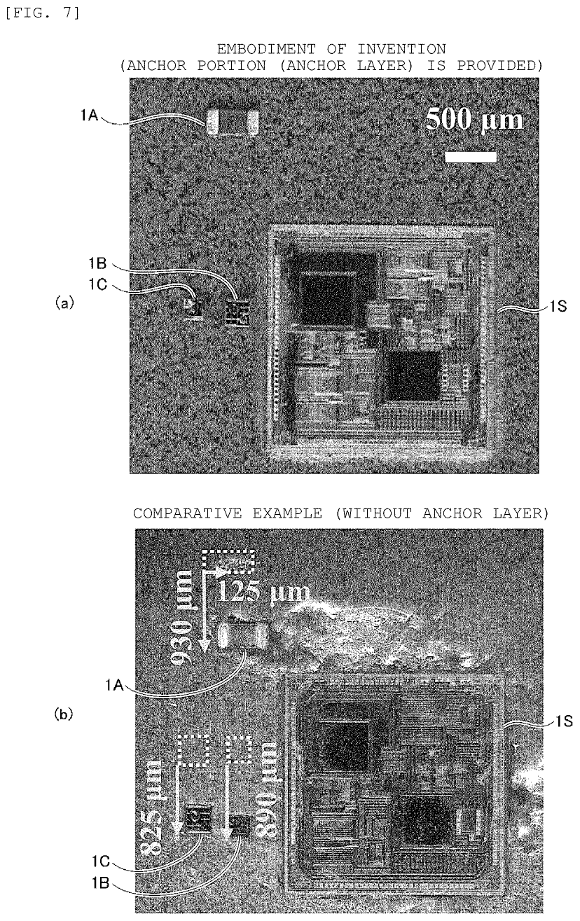

FIG. 7 shows photographs showing the effects of the method for manufacturing a semiconductor device according to the present embodiment of the invention. As the manufacturing method, die-first/face-down FOWLP is adopted. Specifically, (a) of FIG. 7 is a photograph showing an example of a position of the semiconductor chip in a case where the anchor portion (anchor layer) of the semiconductor device according to the present embodiment of the invention is provided. (b) of FIG. 7 is a photograph as a comparative example showing an example of a die shift in a case where no anchor portion is used.

A die shift value is measured by a digital microscope as shown in (a) and (b) of FIG. 7 after the sealing portion 15 is formed by compression-molding PDMS.

A viscosity of a PDMS precursor (the liquid or semi-liquid forming material of the sealing portion 15) is 60 Pas, which is about two to three orders of magnitude lower than that of a normal hard epoxy molding compound (EMC). In addition, the die shift value is measured at a distance of about 20 mm from a wafer center.

As shown in (a) of FIG. 7, on the peeling portion (second peeling portion) provided on the substrate (first substrate), an integrated circuit (size: 2.5 mm/2.5 mm/400 μm: width/length/height) is disposed as a semiconductor chip 1S, a capacitor (size: 1000 μm/500 μm/500 μm: W/L/H) is disposed as a semiconductor chip 1A, a near-infrared micro LED (size: 340 μm/340 μm/270 μm: W/L/H) is disposed as a semiconductor chip 1B, and a red micro LED (size: 270 μm/270 μm/270 μm: W/L/H) is disposed as a semiconductor chip 1C.

In the present embodiment, the semiconductor chip 1S is an integrated circuit (LSI) of a photoplethysmography sensor (PPG sensor) including an LED driver, a photodiode, a storage circuit, and the like.

As shown in (a) of FIG. 7, when the anchor portion (anchor layer) is provided, it is confirmed that the semiconductor chips 1S, 1A, 1B, and 1C are in a state of being disposed at defined positions, and deviation from the defined positions is prevented.

As shown in (b) of FIG. 7, when no anchor portion (anchor layer) is provided as the comparative example, die shifts of the semiconductor chip 1A (capacitor) in an x-axis direction (left-right direction in (b) of FIG. 7) and in a y-axis direction (up-down direction in (b) of FIG. 7) are 125 μm and 930 μm, respectively. A die shift of the semiconductor chip 1B (near-infrared micro LED) is 890 μm, and a die shift of the semiconductor chip 1C (red micro LED) is 825 μm.

This is because bonding strength (bonding force: 0.215 N/mm) between the semiconductor chips 1A, 1B, and 1C, each of which has a small size, and the peeling portion is fairly low.

There are two reasons why the large die shifts occur. The first reason is that a flow of a fluid of the resin that is the material for forming the sealing portion is large, and a large shear force is applied to a side wall of the semiconductor chip, and in particular, there is no barrier wall surrounding the semiconductor chip 1A (capacitor), and thus a large force acts on a thick die.

In addition, the semiconductor chips 1B and 1C (micro LEDs) are moved by the flow of the fluid of the resin along a side wall of the semiconductor chip 1S (LSI chip) that has a large size.

The second reason is that the die shift is caused by bubbling at the time of gas removal from the viscous PDMS (the material for forming the sealing portion) and an interface between a die and a tape in vacuum.

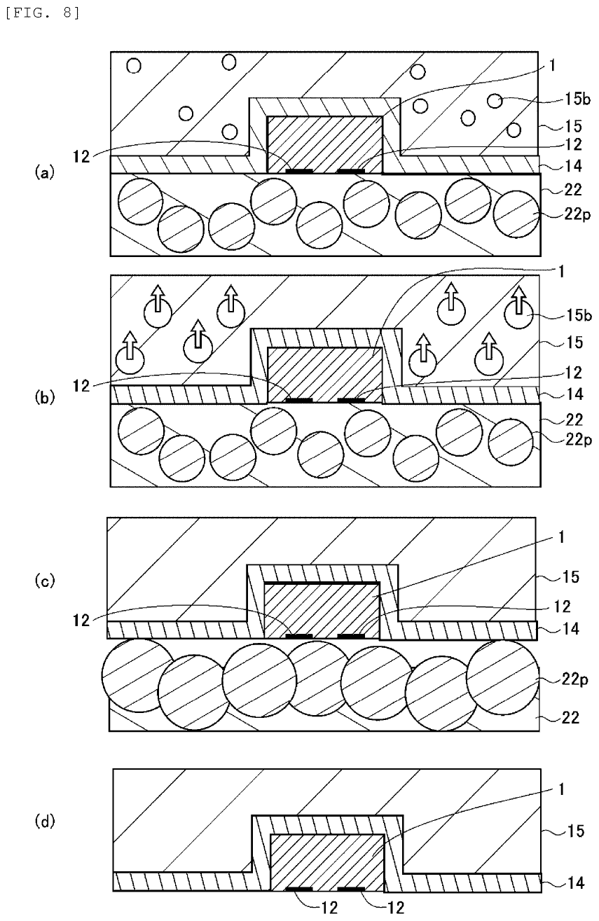

(a) to (d) of FIG. 8 show an example of a mechanism that prevents positional deviation of the semiconductor chip in the case where the anchor portion is provided (the present embodiment of the invention).

Specifically, as shown in (a) of FIG. 8, the semiconductor chip 1 (micro LED or the like) is disposed on the peeling portion 22 provided on the substrate (not shown), and the anchor portion 14 is formed. Then, liquid or semi-liquid PDMS is injected as the material for forming the sealing portion 15. The peeling portion 22 contains expandable particles 22p. The PDMS of the sealing portion 15 contains small bubbles 15b (gas).

Next, as shown in (b) of FIG. 8, a vacuum state is created by a vacuum device, and the bubbles 15b (gas) of the PDMS move upward while expanding, and after gas removal, the PDMS of the sealing portion 15 is cured by applying a high pressure. As shown in (b) of FIG. 8, since the anchor portion 14 is provided, a force of a fluid of the PDMS does not act on the semiconductor chip 1. In addition, even when the bubbles 15b (gas) in the PDMS expand, since the anchor portion 14 is provided, a force caused by the bubbles 15b (gas) in the PDMS does not act on the semiconductor chip 1.

Next, as shown in (c) of FIG. 8, the substrate and the peeling portion 22 are heated to a predetermined temperature to expand the expandable particles 22p of the peeling portion 22, and as shown in (d) of FIG. 8, the peeling portion 22 (first peeling portion) and the like are separated (thermally peeled) from the semiconductor chip 1 and the anchor portion 14. Even when a force acts from the expandable particles 22p of the peeling portion 22 on the semiconductor chip 1, the anchor portion 14 prevents deviation from a prescribed position of the semiconductor chip 1.

Since the die shift is greatly alleviated to be within 5 μm by providing the anchor portion 14, for example, a high-precision mask alignment process or the like can be performed in wiring formation (RDL formation) by a photolithography step in a subsequent step.

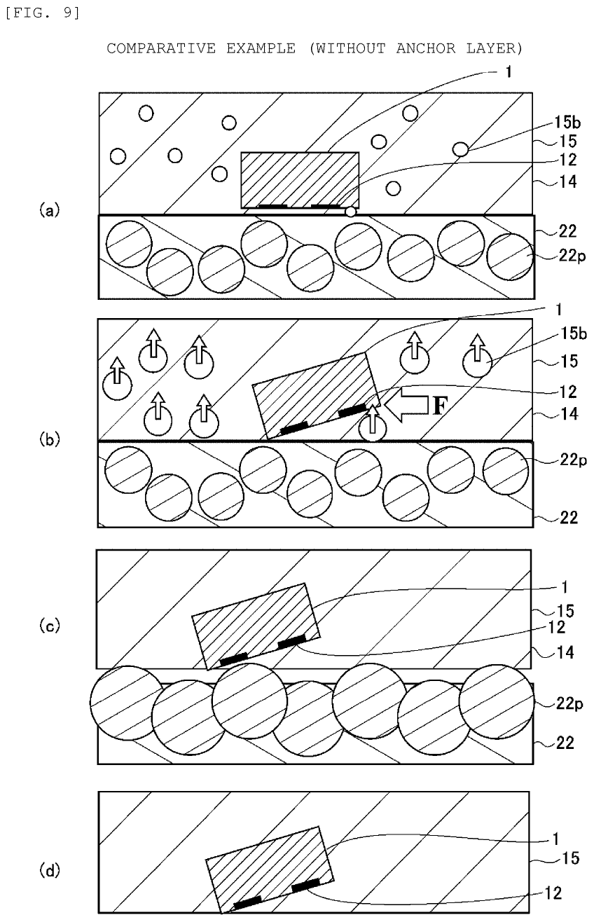

As a comparative example, an example of a mechanism of a die shift in a case where no anchor layer (anchor portion) is used will be described with reference to (a) to (d) of FIG. 9.

As shown in (a) of FIG. 9, the semiconductor chip 1 (micro LED or the like) is disposed on the peeling portion 22 provided on the substrate (not shown), and liquid or semi-liquid PDMS is injected as the material for forming the sealing portion 15.

As shown in (b) of FIG. 9, a force F caused by a flow of a fluid of the PDMS acts on the semiconductor chip 1, and when gas in the PDMS of the sealing portion 15 is removed in a vacuum state by a vacuum device, an upward force caused by the expanded bubbles 15b (gas) acts on the semiconductor chip 1, and thus the semiconductor chip is deviated from the defined position.

As shown in (c) of FIG. 9, when the substrate and the peeling portion 22 are heated to predetermined temperature and the expandable particles 22p of the peeling portion 22 are expanded, a force acts on the semiconductor chip 1 from the expandable particles 22p.

Then, as shown in (d) of FIG. 9, when the peeling portion 22 (first peeling portion) and the like are separated from the semiconductor chip 1 and the sealing portion 15, the semiconductor chip 1 is in a state of being deviated from the defined position.

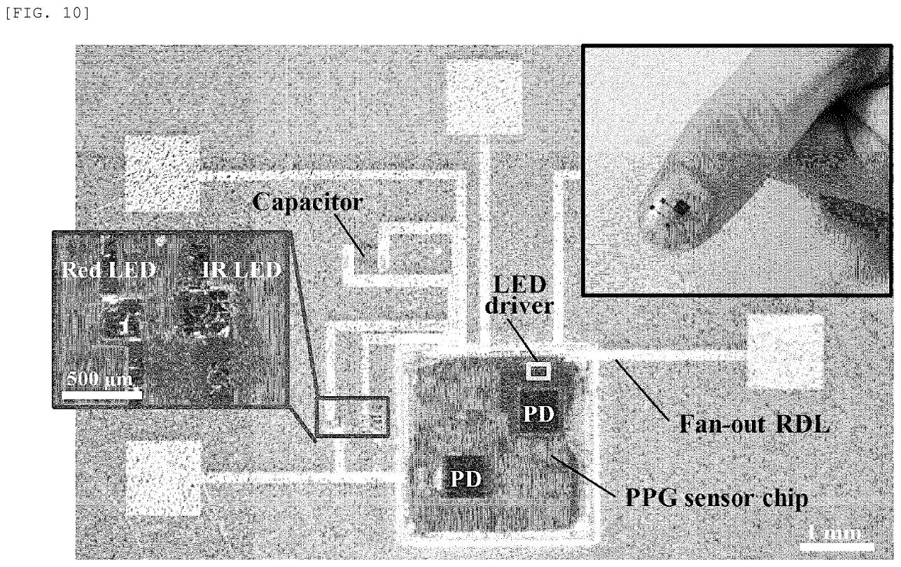

FIG. 10 shows an example of a device provided with a semiconductor device.

The inventors of the present application apply the semiconductor device according to the invention to a photoplethysmography measurement device (physiological measurement device) that can be attached to a nail.

A photoplethysmography measurement device shown in FIG. 10 includes a red micro LED (red LED), a near-infrared micro LED (IRLED), a capacitor, a photoplethysmography (PPG) sensor chip, and the like. The PPG sensor chip is electrically connected by wiring (fan-out RDL) to constituent elements of the photoplethysmography measurement device, such as the red micro LED, the near-infrared micro LED, and the capacitor. The PPG sensor chip includes an LED driver, a light receiving unit (photodiode (PD)), a PPG storage circuit that records a photoelectric volume pulse wave signal, and the like. An upper right portion in FIG. 10 shows a photograph showing an example of the photoplethysmography measurement device (physiological measurement device) in a state of being detachably attached to a nail by a bonding member or the like, and a left portion in FIG. 10 shows an enlarged photograph of the red micro LED and the near-infrared micro LED.

The photoplethysmography measurement device can output red light and near-infrared light from the micro LED in the state of being attached to the nail, receive light reflected by a capillary of a finger by the light receiving unit, and monitor a pulse wave and transcutaneous oxygen saturation (SpO₂) in real time by signal processing.

That is, according to the method for manufacturing a semiconductor device according to the present invention, it is possible to produce a highly integrated, thin, and freely bendable semiconductor device and a physiological measurement device.

As described above, the method for manufacturing the semiconductor device 100 according to the present embodiment of the invention includes: disposing the semiconductor chip 1 such that the electrode 12 of the semiconductor chip 1 is abutted against the peeling portion 22 (also referred to as a first peeling portion or a first thermal peeling portion) provided on the substrate 21 (also referred to as a first substrate) (ST1, ST2); forming the anchor portion 14 (anchor layer) defining the position of the semiconductor chip 1 such that the anchor portion 14 covers the peeling portion 22 (first thermal peeling portion) and the semiconductor chip 1 (ST3); forming the sealing portion 15 (PDMS or the like) abutted against the anchor portion 14 (ST4); separating the peeling portion 22 (first thermal peeling portion) and the substrate 21 (first substrate) from the semiconductor chip 1 and the anchor portion 14 and exposing the electrode 12 of the semiconductor chip 1 (ST6), and the like.

Specifically, in step ST3, the anchor portion 14 is formed so as to cover the portion of the semiconductor chip 1 other than the surface on which the electrode 12 is formed.

In addition, in the method for manufacturing the semiconductor device 100, die-first/face-down FOWLP is adopted as the method for mounting the semiconductor chip 1.

That is, in semiconductor packaging, by forming the anchor portion 14 that defines the position of the semiconductor chip 1 as described above, the deviation of the semiconductor chip 1 from the defined position can be prevented by the anchor portion 14, and it is possible to provide a method for manufacturing a semiconductor device that manufactures the highly integrated semiconductor device 100 in which the semiconductor chip 1 is disposed at the defined position with high accuracy.

That is, it is possible to provide a method for manufacturing a semiconductor device that prevents a die shift in semiconductor packaging.

In addition, it is preferable that the peeling portion 22 and the anchor portion 14 have a certain degree of bonding force so as not to be deviated in an in-plane direction at an interface therebetween. In a case where a thermal peeling material is adopted as the peeling portion 22, the peeling portion 22 is thermally peeled from the anchor portion 14 easily when heated to a temperature at which thermal peeling occurs or a temperature slightly higher than the temperature.

In addition, for example, at the time of forming the anchor portion 14 or at the time of forming the sealing portion 15, even when the semiconductor chip 1 is deviated from the defined position by about 0.1 μm to 5 μm, the deviation is within a margin of error, which is included in the prevention of the deviation of the semiconductor chip 1 from the defined position by the anchor portion 14.

In addition, it is preferable that the anchor portion 14 and the sealing portion 15 (PDMS or the like) have a certain degree of bonding force so as not to be deviated in an in-plane direction at an interface therebetween. In a case where a thermal peeling material is adopted as the peeling portion 22 or the peeling portion 23, even when the anchor portion 14 or the sealing portion 15 is heated to a temperature at which thermal peeling occurs in a thermal peeling step or a temperature slightly higher than the temperature, a bonding force effectively acts at the interface between the anchor portion 14 and the sealing portion 15 (PDMS or the like) so that the anchor portion 14 and the sealing portion 15 are not separated from each other.

In addition, in a case where a plurality of semiconductor chips 1 are arranged on the peeling portion 22 (first peeling portion) provided on the substrate 21 (first substrate), even when a thickness (height) of each semiconductor chip 1 varies, the semiconductor chip 1 is disposed in such a manner that the electrode 12 of the semiconductor chip 1 is abutted against the peeling portion 22 provided on the substrate 21, the anchor portion 14 is formed to define the position of the semiconductor chip 1 (ST3), the sealing portion 15 (PDMS or the like) is formed (ST4), and the peeling portion 22 and the substrate 21 are separated, so that it is possible to provide a method for manufacturing a semiconductor device by which the electrode 12 of each semiconductor chip 1 can be located at the defined position in the same plane with high accuracy.

The method for manufacturing a semiconductor device according to the present embodiment of the invention further includes forming the wiring 17 connected to the electrode 12 of the semiconductor chip 1 (ST7) after exposing the electrode 12 of the semiconductor chip 1 (ST6).

That is, it is possible to provide a method for manufacturing a semiconductor device by which the wiring 17 is formed with high accuracy on the electrode 12 of the semiconductor chip 1 that is disposed with high accuracy at the defined position.

In addition, in the method for manufacturing a semiconductor device according to the present embodiment of the invention, the anchor portion 14 is formed by at least one of a vapor phase deposition method, a spin coating method, a spray coating method, and an inkjet method.

That is, the anchor portion 14 (anchor layer) can be easily formed by one of the vapor phase deposition method, the spin coating method, the spray coating method, and the like. By forming the anchor portion 14, the semiconductor chip 1 is not deviated from the defined position, and is disposed at a predetermined position with high accuracy.

In addition, even when the sealing portion 15 (PDMS or the like) is formed so as to be abutted against the anchor portion 14, no force directly acts on the semiconductor chip 1 at the time of injecting the sealing material of the sealing portion 15, and thus it is possible to prevent the semiconductor chip 1 from being deviated from the defined position.

In particular, by forming the anchor portion 14 described above by the vapor phase deposition method, the position of the semiconductor chip 1 can be prescribed, and the deviation from the defined position can be easily prevented.

In addition, the semiconductor device 100 according to the present embodiment of the invention is the semiconductor device 100 manufactured by the method for manufacturing a semiconductor device described above, and specifically includes the semiconductor chip 1 whose one surface is formed with the electrode 12, the anchor portion 14 covering the semiconductor chip 1 other than the surface on which the electrode 12 is formed, the sealing portion 15 (PDMS or the like) abutted against the anchor portion 14, the wiring 17 connected to the electrode 12 of the semiconductor chip 1, and the like.

That is, in the semiconductor device 100 manufactured by the method for manufacturing a semiconductor device described above, the anchor portion 14 covers the semiconductor chip 1 other than the surface on which the electrode 12 is formed, and the sealing portion 15 (PDMS or the like) is formed so as to be abutted against the anchor portion 14, so that it is possible to provide the highly integrated semiconductor device 100 with high accuracy without deviation from the defined position.

In addition, in the semiconductor device 100, when the sealing portion 15 or the like is formed of a material having flexibility, the semiconductor device 100 can be flexibly bent, and positional deviation of the semiconductor chip 1 is small even in a bent state since the anchor portion 14 is provided.

In addition, the method for manufacturing a device provided with a semiconductor device according to the present embodiment of the invention includes manufacturing a device by combining another component with the semiconductor device 100 manufactured by the method for manufacturing a semiconductor device described above. That is, it is possible to easily provide a method for manufacturing a device provided with the semiconductor device 100.

In addition, the device according to the present embodiment of the invention includes the semiconductor device 100. The device including the semiconductor device 100 may be an electronic device, for example, a portable information processing device such as a smartphone or a mobile phone, a medical device, or a device other than an electronic device, and the device is included in the scope of the claims as long as the device includes the semiconductor device 100 described above.

Although the present embodiment of the invention is described in detail above with reference to the drawings, the specific configuration is not limited to the present embodiment, and design changes and the like within a range not departing from the gist of the present invention are also included in the invention.

In addition, described contents of embodiments shown in the drawings described above can be combined with each other unless there is a particular contradiction or problem in purposes, configurations, or the like of the embodiments.

In addition, the description of each drawing can be an independent embodiment, and the present embodiment of the invention is not limited to be one embodiment combining the respective drawings.

For example, the method for manufacturing a semiconductor device according to the present embodiment of the invention may include forming an insulating layer (buffer portion) made of an insulating material between the anchor portion 14 and the semiconductor chip 1 or between the anchor portion 14 and the sealing portion 15, or both between the anchor portion 14 and the semiconductor chip 1 and between the anchor portion 14 and the sealing portion 15.

The insulating layer (buffer portion) can increase a bonding force between the anchor portion 14 and the semiconductor chip 1 or the sealing portion 15 by providing an insulating layer made of a material that increases a bonding force of a boundary portion when the bonding force between the anchor portion 14 and the semiconductor chip 1 or the sealing portion 15 is small.

In addition, when the anchor portion 14 is made of a conductive material, an insulating layer (buffer portion) is formed between the anchor portion 14 and the semiconductor chip 1 or between the anchor portion 14 and the sealing portion 15 or both between the anchor portion 14 and the semiconductor chip 1 and between the anchor portion 14 and the sealing portion 15, thereby preventing electric leakage from the anchor portion 14.

### REFERENCE SIGNS LIST

1: semiconductor chip
12: electrode (electrode of semiconductor chip)
14: anchor portion (anchor layer or the like)
15: sealing portion (PDMS or the like)
16: buffer layer
17: wiring (rewiring layer or the like)
21: substrate (first substrate)
22: peeling portion (first peeling portion)
23: peeling portion (second peeling portion)
24: substrate (second substrate)
100: semiconductor device

1. A method for manufacturing a semiconductor device provided with a semiconductor chip, the method comprising:
disposing the semiconductor chip such that an electrode of the semiconductor chip is abutted against a peeling portion provided on a substrate;
forming an anchor portion, which defines a position of the semiconductor chip and has flexibility so as to be freely bendable, such that the anchor portion covers the peeling portion and the semiconductor chip;
forming a sealing portion that is abutted against the anchor portion and has flexibility so as to be freely bendable; and
separating the peeling portion and the substrate from the semiconductor chip and the anchor portion and exposing the electrode of the semiconductor chip.

2. The method for manufacturing a semiconductor device according to claim 1, further comprising: forming a wiring connected to the electrode after exposing the electrode of the semiconductor chip.

3. The method for manufacturing a semiconductor device according to claim 1, wherein the anchor portion is any one of a combination of 4,4′-diaminodiphenylmethane and 4,4′-diphenylmethane diisocyanate, a combination of 1,9-diaminononane and 1,9-diisocyanate nonane, and a combination of 1,5-diaminopentane and 1,5-diisocyanate pentane.

4. The method for manufacturing a semiconductor device according to claim 2, wherein the anchor portion is any one of a combination of 4,4′-diaminodiphenylmethane and 4,4′-diphenylmethane diisocyanate, a combination of 1,9-diaminononane and 1,9-diisocyanate nonane, and a combination of 1,5-diaminopentane and 1,5-diisocyanate pentane.

5. The method for manufacturing a semiconductor device according to claim 1, wherein the anchor portion is formed by a vapor phase deposition method, a spray coating method, or an inkjet method.

6. The method for manufacturing a semiconductor device according to claim 3, wherein the anchor portion is formed by a vapor phase deposition method, a spray coating method, or an inkjet method.

7. The method for manufacturing a semiconductor device according to claim 1, wherein the anchor portion is formed so as to cover a portion of the semiconductor chip other than a surface on which the electrode is formed.

8. The method for manufacturing a semiconductor device according to claim 3, wherein the anchor portion is formed so as to cover a portion of the semiconductor chip other than a surface on which the electrode is formed.

9. The method for manufacturing a semiconductor device according to claim 1, further comprising: forming an insulating layer between the anchor portion and the semiconductor chip or between the anchor portion and the sealing portion, or both between the anchor portion and the semiconductor chip and between the anchor portion and the sealing portion.

10. The method for manufacturing a semiconductor device according to claim 3, further comprising: forming an insulating layer between the anchor portion and the semiconductor chip or between the anchor portion and the sealing portion, or both between the anchor portion and the semiconductor chip and between the anchor portion and the sealing portion.

11. A method for manufacturing a device provided with a semiconductor device, the method comprising: manufacturing a device by combining another component with a semiconductor device manufactured by the method for manufacturing a semiconductor device according to claim 1.

12. A method for manufacturing a device provided with a semiconductor device, the method comprising: manufacturing a device by combining another component with a semiconductor device manufactured by the method for manufacturing a semiconductor device according to claim 2.

13. A method for manufacturing a device provided with a semiconductor device, the method comprising: manufacturing a device by combining another component with a semiconductor device manufactured by the method for manufacturing a semiconductor device according to claim 3.

14. A method for manufacturing a device provided with a semiconductor device, the method comprising: manufacturing a device by combining another component with a semiconductor device manufactured by the method for manufacturing a semiconductor device according to claim 4.

15. A semiconductor device comprising:
a semiconductor chip whose one surface is formed with an electrode;
an anchor portion that covers the semiconductor chip other than the surface on which the electrode is formed, and has flexibility so as to be freely bendable;
a sealing portion that is abutted against the anchor portion and has flexibility so as to be freely bendable; and
a wiring connected to the electrode of the semiconductor chip.

16. The semiconductor device according to claim 15, wherein the anchor portion is any one of a combination of 4,4′-diaminodiphenylmethane and 4,4′-diphenylmethane diisocyanate, a combination of 1,9-diaminononane and 1,9-diisocyanate nonane, and a combination of 1,5-diaminopentane and 1,5-diisocyanate pentane.

17. A device comprising: the semiconductor device according to claim 15.

18. A device comprising: the semiconductor device according to claim 16.
